(19) United States
(12) Patent Application Publication
(10) Pub. No.: US 2025/0192130 A1
(43) Pub. Date: Jun. 12, 2025

(54) SYSTEM-ON-CHIP, INTEGRATED CIRCUIT ASSEMBLY, AND PROCESSING METHOD THEREOF

(71) Applicant: Alibaba Innovation Private Limited, Singapore (SG)

(72) Inventors: Yijin Guan, Beijing (CN); Tianchan Guan, Shanghai (CN); Zhaoyang Du, Beijing (CN); Shuangchen Li, Sunnyvale, CA (US); Dimin Niu, Sunnyvale, CA (US); Hongzhong Zheng, Los Gatos, CA (US)

(21) Appl. No.: 18/974,615

(22) Filed: Dec. 9, 2024

(30) Foreign Application Priority Data
Dec. 11, 2023 (CN) 202311690774.7

(51) Int. Cl. H01L 25/18; H01L 21/48; H01L 23/00; H01L 23/48; H01L 23/498; H10B 80/00

(52) U.S. Cl. CPC H01L 25/18; H01L 21/4857; H01L 21/486; H01L 23/481; H01L 23/49822; H01L 23/49833; H01L 23/49838; H01L 24/08; H01L 2224/08225; H01L 2924/1431; H10B 80/00

(57) ABSTRACT

An integrated circuit assembly includes a first die formed by a first wafer layer and a first insulation layer, a second die formed by a second wafer layer and a second insulation layer, a third die formed by a third wafer layer, a third insulation layer, and a fourth insulation layer. A first semiconductor device is formed in the first wafer layer and forms a first bonding point on the first insulation layer. A second semiconductor device is formed in the second wafer layer and forms a second bonding point on the second insulation layer. A third bonding point of the third insulation layer and a fourth bonding point of the fourth insulation layer are connected through the interior of the third wafer layer. The third insulation layer and the first insulation layer are hybrid bonded and the fourth insulation layer and the second insulation layer are hybrid bonded.

### CROSS-REFERENCE TO RELATED APPLICATIONS

This application claims priority to Chinese Patent Application No. 202311690774.7, filed with the China National Intellectual Property Administration on Dec. 11, 2023, and entitled “System-on-Chip, Integrated Circuit Assembly, and Processing Method Thereof,” which is incorporated herein by reference in its entirety.

### TECHNICAL FIELD

The embodiments of the present invention relate to the field of computer technology, and more specifically, to a system-on-chip, an integrated circuit assembly, and the processing method thereof.

### BACKGROUND

AI (Artificial Intelligence) applications or HPC (High Performance Computing) applications, including but not limited to Large Language Models (LLMs), recommendation systems, and Graph Neural Networks (GNNs), place significant pressure on memory performance. An effective solution to this challenge is processing-near-memory (PNM) technology based on 2.5D/3D wafer stacking, which integrates high-bandwidth memory devices and logic devices within the same chip package.

The hybrid bonding process in conventional 3D wafer packaging requires the alignment or proximity of bonding points between dies, such as those of logic devices and memory devices. This necessitates the rearrangement of devices and circuitry on both dies, which results in lower efficiency during the processing and manufacturing of 3D wafer packaging.

### SUMMARY

In view of the above, the embodiments of the present invention provide a system-on-chip, an integrated circuit assembly, and a processing method thereof to at least partially address the aforementioned issues.

According to a first aspect of the embodiments of the present invention, an integrated circuit assembly is provided, comprising: a first bare die, formed by a first wafer layer and a first insulation layer, wherein a first semiconductor device is formed in the first wafer layer, and the first semiconductor device forms a first bonding point on the first insulation layer; a second bare die, formed by a second wafer layer and a second insulation layer, wherein a second semiconductor device is formed in the second wafer layer, and the second semiconductor device forms a second bonding point on the second insulation layer; a third bare die, formed by a third wafer layer, a third insulation layer, and a fourth insulation layer, wherein the third insulation layer forms a third bonding point and the fourth insulation layer forms a fourth bonding point, and the third bonding point and the fourth bonding point are electrically connected through the interior of the third wafer layer. The third bare die is positioned between the first bare die and the second bare die, with the third insulation layer and the first insulation layer are hybrid bonded by aligning the third bonding point with the first bonding point, and the fourth insulation layer and the second insulation layer are hybrid bonded by aligning the fourth bonding point with the second bonding point.

In another embodiment of the present invention, a through via is formed in the third bare die, and the third bonding point is electrically connected to the fourth bonding point via the through via.

In another embodiment of the present invention, a first routing point is formed at the through via in the third insulation layer, and a second routing point is formed at the through via in the fourth insulation layer. The first routing point is electrically connected to the third bonding point via an internal routing layer within the third insulation layer, and the second routing point is electrically connected to the fourth bonding point via an internal routing layer within the fourth insulation layer. The first routing point and the second routing point are electrically connected inside the through via.

In another embodiment of the present invention, a distance between the first routing point and the third bonding point in an extending direction of each wafer layer is less than the distance between the first bonding point and the second bonding point in the extending direction. Similarly, the distance between the second routing point and the fourth bonding point in the extending direction of each wafer layer is less than the distance between the first bonding point and the second bonding point in the extending direction.

In another embodiment of the present invention, a third semiconductor device is formed outside a reserved location of the through via in an extending direction of the third wafer layer.

In another embodiment of the present invention, the third semiconductor device is located on a side of the third wafer that is closer to the fourth insulation layer.

In another embodiment of the present invention, the third semiconductor device is electrically connected to an internal routing layer of the third insulation layer outside the reserved position of the through via, and/or the third semiconductor device is electrically connected to the internal routing layer of the fourth insulation layer outside the reserved location of the through via.

In another embodiment of the present invention, the first semiconductor device is a logic device, and the second semiconductor device is a memory device.

According to a second aspect of the embodiments of the present invention, a method for processing an integrated circuit assembly is provided, comprising: forming a third initial insulation layer and a fourth initial insulation layer on both surfaces of a third wafer layer, respectively; forming a through via extending through the third wafer layer at a reserved location in an extending direction of the third wafer layer; forming routing layers at a first routing point in the third initial insulation layer based on the through via, and forming a routing layer at a second routing point formed in the fourth initial insulation layer based on the through via; forming a third bonding point in the routing layer of the third initial insulation layer, aligned with a first bonding point of a first bare die, and forming a fourth bonding point in the routing layer of the fourth initial insulation layer, aligned with a second bonding point of a second bare die; depositing an insulation layer on the routing layer of the third initial insulation layer to form a third insulation layer, and depositing an insulation layer on the routing layer of the fourth initial insulation layer to form a fourth insulation layer.

In another embodiment of the present invention, the method further includes: forming a third semiconductor device outside the reserved location in the extending direction of the third wafer layer; forming a third initial insulation layer and a fourth initial insulation layer on both surfaces of the third wafer layer, including: forming the fourth initial insulation layer on a side of the third wafer layer where the third semiconductor device is formed, and forming the third initial insulation layer on the opposite side of the third wafer layer.

In another embodiment of the present invention, the method further includes: depositing a first insulation layer on the side of a first wafer layer where a first semiconductor device is formed to create the first bare die; depositing a second insulation layer on the side of a second wafer layer where the second semiconductor device is formed to create the second bare die.

According to a third aspect of the embodiments of the present invention, a system-on-chip is provided, comprising an integrated circuit assembly described in the first aspect.

In the embodiment of the present invention, the third bare die is formed by a third wafer layer, a third insulation layer, and a fourth insulation layer. The third insulation layer and the first insulation layer are hybrid bonded by aligning the third bonding point with the first bonding point, while the fourth insulation layer and the second insulation layer are hybrid bonded by aligning the fourth bonding point with the second bonding point. As a result, the third bare die can reliably match and be compatible with the first bonding point of the first bare die and the second bonding point of the second bare die through the third and fourth bonding points. Additionally, the third bonding point and the fourth bonding point are electrically connected through the interior of the third wafer layer, thereby achieving the electrical connection between the first bonding point and the second bonding point. This ensures data transmission between the first semiconductor device and the second semiconductor device. Furthermore, other semiconductor devices can be integrated into the third wafer layer of the third bare die, which is compatible with 3D wafer stacking technology, improving the processing efficiency of 3D wafer packaging.

### BRIEF DESCRIPTION OF THE DRAWINGS

To more clearly illustrate the technical solutions of the embodiments of the present invention or the prior art, a brief introduction of the drawings used in the description of the embodiments or the prior art is provided below. It is evident that the drawings described below are merely some examples disclosed in the embodiments of the present invention. For those skilled in the art, other drawings may also be derived from these drawings.

FIG. 1 is a schematic side view of an integrated circuit assembly according to one example.

FIG. 2 is a schematic side view of an integrated circuit assembly according to another example.

FIG. 3 is a schematic structural diagram of an integrated circuit assembly in some embodiments of the present invention.

FIG. 4 is a schematic side view of some examples of the integrated circuit assembly in the embodiment of FIG. 3.

FIG. 5 is a flowchart illustrating the steps of a processing method for an integrated circuit assembly in other embodiments of the present invention.

### DETAIL DESCRIPTION OF THE EMBODIMENTS

To enable those skilled in the art to better understand the technical solutions in the embodiments of the present invention, the technical solutions in the embodiments of the present invention will be clearly and thoroughly described below in conjunction with the accompanying drawings of the embodiments. It is evident that the described embodiments are only part of the embodiments of the present invention, not all embodiments. Based on the embodiments of the present invention, all other embodiments obtained by those skilled in the art should fall within the scope of protection of the embodiments of the present invention.

The following detailed description makes reference to the accompanying drawings, which form a part of the detailed description and illustrate exemplary embodiments. It should be understood that other embodiments may be utilized, and structural and/or logical changes may be made without departing from the scope of the claimed subject matter. It should also be noted that directional references (such as upper, lower, top, bottom, etc.) are used merely to facilitate the description of the features in the drawings. Therefore, the following detailed description should not be interpreted in a limiting sense, and the scope of the claimed subject matter is defined only by the appended claims and their equivalents.

In the following description, numerous details are set forth. However, it will be apparent to those skilled in the art that the embodiments described herein can be practiced without these specific details. In some instances, well-known methods and devices are shown in block diagram form rather than in detail, to avoid obscuring the embodiments. Throughout this specification, references to “an embodiment,” “one embodiment,” or “some embodiments” mean that a particular feature, structure, function, or characteristic described in connection with that embodiment is included in at least one embodiment of the invention. Therefore, the phrases “in an embodiment,” “in one embodiment,” or “in some embodiments” appearing throughout this specification are not necessarily referring to the same embodiment. Moreover, in one or more embodiments, specific features, structures, functions, or characteristics may be combined in any suitable manner. For example, a first embodiment can be combined with a second embodiment in any situation where the specific features, structures, functions, or characteristics associated with the two embodiments are not mutually exclusive.

As used in the description and the appended claims, the singular forms “a,” “an,” and “the” are intended to include the plural forms as well, unless the context clearly indicates otherwise. It will also be understood that the term “and/or” as used herein refers to and includes any and all possible combinations of one or more of the associated listed items.

The terms “coupled” and “connected,” along with their derivatives, may be used herein to describe the functional or structural relationship between components. It should be understood that these terms are not intended to be synonymous. Instead, in specific embodiments, “connected” may be used to indicate that two or more elements are in direct physical, optical, or electrical contact with each other. “Coupled” may be used to indicate that two or more elements are in direct or indirect physical or electrical contact (with other intermediate elements between them), and/or that two or more elements cooperate or interact with each other (e.g., in a causal relationship).

As used herein, the terms “above,” “below,” “between,” and “on” refer to the relative positioning of one component or material with respect to other components or materials, where such physical relationships are notable. For example, in the context of materials, a material positioned “above” or “below” another material may either be in direct contact or may have one or more intermediate materials between them. Additionally, a material positioned “between” two materials may either be in direct contact with both layers or may have one or more intermediate layers. In contrast, a first material “on” a second material indicates that the first material is in direct contact with the second material. Similar distinctions apply in the context of component assembly.

As used throughout this description and in the claims, the phrases “at least one of” or “one or more of” in connection with a list of items may mean any combination of the listed items. For example, the phrase “at least one of A, B, or C” may mean A; B; C; A and B; A and C; B and C; or A, B, and C.

The terms “circuit” or “module” may refer to one or more passive and/or active components that are arranged to work together to provide the desired function. The term “signal” may refer to at least one current signal, voltage signal, or magnetic signal. The terms “substantially,” “near,” “approximately,” “close to,” and “about” generally refer to being within +/−10% of the target value.

The following provides a further detailed explanation of the specific implementations of the embodiments of the present invention in conjunction with the accompanying drawings.

The wafer layer is made of pure silicon (Si) and consists of a front side and a back side. The front side of the wafer is the primary working surface for chip fabrication. It typically has a specific orientation and lattice structure, which is used for growing or building transistors, circuits, and other semiconductor devices; in other words, the front side is equipped with routing layers. The back side of the wafer, also known as the backside or substrate, is opposite to the front side. The back side is typically flat, without a crystal structure, and serves to provide mechanical stability and support for handling the wafer. The back side generally lacks circuits or devices but may undergo special treatment or coating to meet specific needs, such as enhancing adhesion or improving thermal conductivity.

3D wafer-level packaging refers to an integrated circuit assembly consisting of two or more wafer layers packaged together.

Hybrid bonding (HB) is a method used to achieve denser interconnections between stacked chips. The hybrid bonding process allows for face-to-face stacking of wafers.

Through-Silicon Vias (TSVs) primarily serve the function of electrical extension and interconnection along the Z-axis (the axis perpendicular to the plane of the wafer layer).

The Re-distribution Layer (RDL) serves the function of electrical extension and interconnection in the XY plane (the plane of the wafer layer). In advanced packaging technologies like Fan-In Wafer Level Package (FIWLP) and Fan-Out Wafer Level Package (FOWLP), RDL is a critical technology. It allows the IO pads to be redistributed in either a fan-in or fan-out configuration, forming different types of wafer-level packaging.

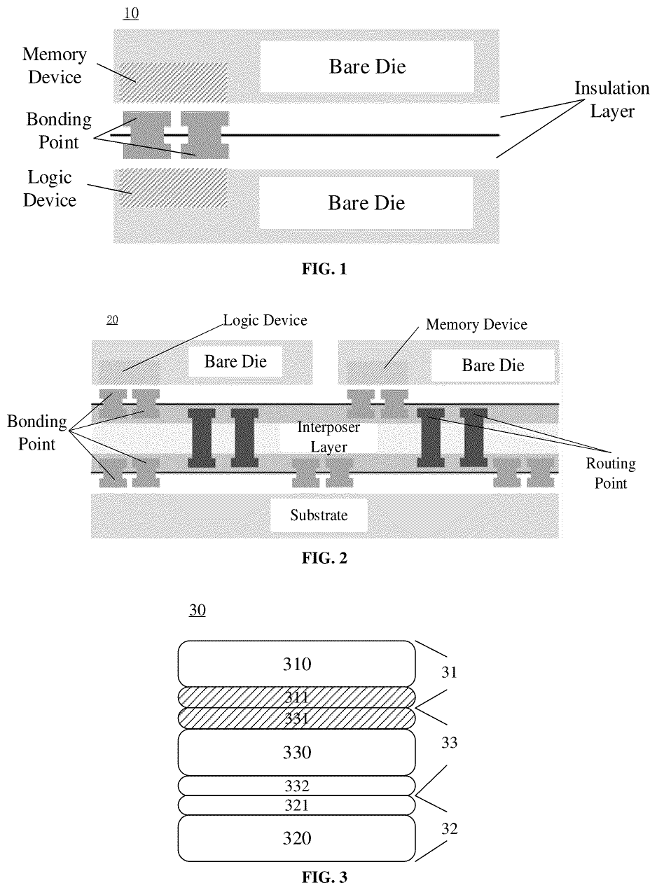

Generally, a high-density, high-energy-efficiency near-memory computing solution is constructed by adopting Hybrid Bonding (HB) technology between logic devices and memory devices. In addition to the significant advantage of on-chip memory capacity, wafer-to-wafer hybrid bonding technology can also provide high-bandwidth integrated solutions with higher energy efficiency. In the example of FIG. 1, the entire chip of the integrated circuit assembly 10 (i.e., the chip package) is formed by stacking two bare dies. Logic devices are formed in the wafer layer of the bottom bare die, and memory devices are formed in the wafer layer of the top bare die. In this example, the positions of the logic devices and the memory devices are uniformly designed and laid out. The bonding points between the memory devices and the logic devices that access the memory devices are located at corresponding positions of the memory and logic devices, respectively. The face-to-face bonding of the two bare dies is achieved through the hybrid bonding of the insulation layers of the top bare die and the bottom bare die, wherein the bonding points serve both as electrical connection carriers and as support material between the two bare dies.

It is evident that if the memory devices and logic devices are not uniformly designed and laid out in corresponding positions, face-to-face bonding becomes difficult to achieve. Therefore, only custom chips with a dedicated layout can be directly stacked at the bonding points. Without any redesign, it is impossible to reliably and efficiently use pre-manufactured bare dies.

FIG. 2 illustrates an integrated circuit assembly 20 in another example of 2.5D wafer stacking. In this example, an electrical connection is established between the bare die containing logic devices and the bare die containing memory devices by stacking an interposer layer on a substrate. Specifically, the interposer layer is hybrid bonded to the bonding points of both bare dies. In this example, the two bare dies can be pre-manufactured dies, meaning that after the manufacturing of the two dies is complete, the interposer layer is stacked between the two bare dies and the substrate, thereby forming a chip package. This stacking method can be referred to as 2.5D interposer technology, which does not require specific layout constraints for the positions of the memory and logic devices.

However, the 2.5D interposer technology introduces additional area overhead as well as the cost of Through-Silicon Vias (TSV), the interposer, and the substrate. Moreover, the bandwidth and capacity that the memory devices can provide to the logic devices are also limited.

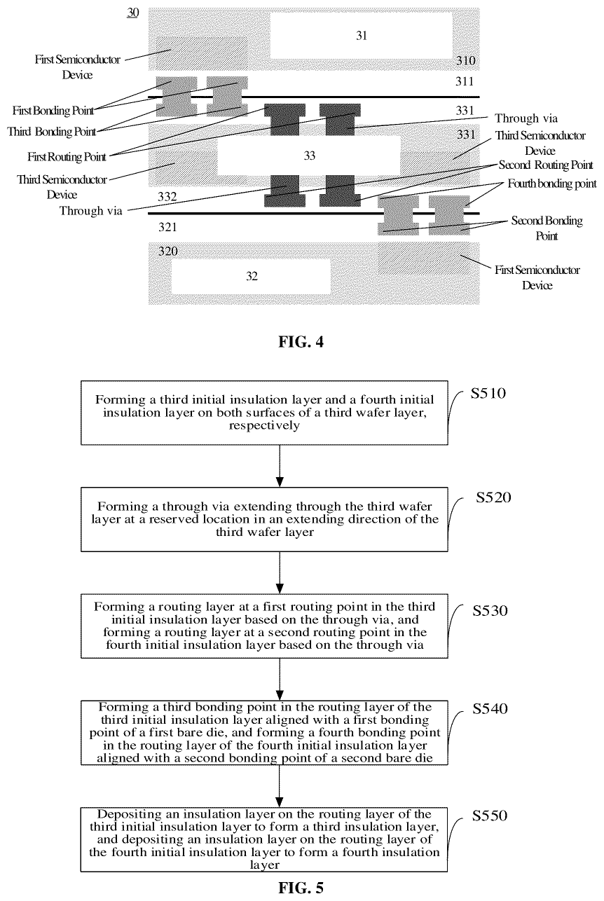

FIG. 3 illustrates an integrated circuit assembly in accordance with some embodiments of the present invention. The integrated circuit assembly shown in FIG. 3 can be implemented as a 3D stacked package. The integrated circuit assembly 30 in FIG. 3 includes a first bare die 31, a second bare die 32, and a third bare die 33. The third bare die 33, also referred to as a routing die, is positioned between the first bare die 31 and the second bare die 32.

The first bare die 31 is formed by a first wafer layer 310 and a first insulation layer 311, with the first semiconductor devices being formed in the first wafer layer 310. The first semiconductor devices create first bonding points on the first insulation layer 311. The second bare die 32 is formed by a second wafer layer 320 and a second insulation layer 321, with the second semiconductor devices being formed in the second wafer layer 320. The second semiconductor devices create second bonding points on the second insulation layer 321.

It should be understood that the first semiconductor device can be a logic device or a memory device, and the second semiconductor device can also be a logic device or a memory device. When both the first and second semiconductor devices are memory devices, the integrated circuit assembly enables data transfer between memory devices. When both the first and second semiconductor devices are logic devices, the integrated circuit assembly facilitates parallel computation between the logic devices. In the case where the first semiconductor device is a memory device and the second semiconductor device is a logic device, the integrated circuit assembly enables high-bandwidth near-memory computing.

Additionally, the third bare die 33 is formed by a third wafer layer 330, a third insulation layer 331, and a fourth insulation layer 332. Third bonding points are formed on the third insulation layer 331, and fourth bonding points are formed on the fourth insulation layer 332. The third bonding points and fourth bonding points are electrically connected through the interior of the third wafer layer 330.

Additionally, the third insulation layer 331 and the first insulation layer 311 are hybrid bonded by aligning the third bonding points with the first bonding points, while the fourth insulation layer 332 and the second insulation layer 321 are hybrid bonded by aligning the fourth bonding points with the second bonding points.

In the embodiments of the present invention, the third bare die is formed by a third wafer layer, a third insulation layer, and a fourth insulation layer. The third insulation layer and the first insulation layer are hybrid bonded by aligning the third bonding points with the first bonding points, and the fourth insulation layer and the second insulation layer are hybrid bonded by aligning the fourth bonding points with the second bonding points. Thus, the third bare die, through the third bonding points and fourth bonding points, can reliably match and be compatible with the first bonding points of the first bare die and the second bonding points of the second bare die. Furthermore, the third bonding points and the fourth bonding points are electrically connected through the interior of the third wafer layer, enabling the electrical connection between the first bonding points and the second bonding points. This ensures data transfer between the first semiconductor device and the second semiconductor device. Additionally, other semiconductor devices can be arranged in the third wafer layer of the third bare die, which enhances compatibility with 3D wafer stacking technology and improves the processing efficiency of 3D wafer packaging.

In other examples, as shown in FIG. 4, through vias are formed in the third bare die, and the third bonding points are electrically connected to the fourth bonding points via the through vias. This effectively enables routing within the space of the third wafer layer.

Furthermore, in some examples, a first routing point is formed at the through via in the third insulation layer, and a second routing point is formed at the through via in the fourth insulation layer. The first routing point is electrically connected to the third bonding point through an internal routing layer within the third insulation layer, and the second routing point is electrically connected to the fourth bonding point through an internal routing layer within the fourth insulation layer. The first routing point and the second routing point are electrically connected inside the through via. This configuration further provides space for additional third semiconductor devices in the third wafer layer, as the internal routing layers within the insulation layers do not occupy the internal space of the third wafer layer, thus enhancing the compactness of devices within the third wafer layer.

Furthermore, in some examples, the distance between the first routing point and the third bonding point in the extending direction of each wafer layer is shorter than the distance between the first bonding point and the second bonding point in the extending direction. Similarly, the distance between the second routing point and the fourth bonding point in the extending direction of each wafer layer is shorter than the distance between the first bonding point and the second bonding point in the extending direction. This design maintains the flexibility of the electrical connection between the first and second bare dies while minimizing the routing length within the internal routing layer as much as possible.

In other examples, as shown in FIG. 4, two third semiconductor devices are positioned without occupying the space of the through vias. The metal in the through vias (e.g., Through-Silicon Vias, TSVs) is similar to the metal in the routing layer and can be formed through electroplating. Generally, third semiconductor devices are formed outside the reserved locations for the through vias in the extending direction of the third wafer layer. In other words, the third semiconductor devices can be implemented as memory devices or logic devices, thereby utilizing the available space in the third wafer layer of the third bare die while maintaining connectivity between the first and second bare dies. This enhances the overall integration of the integrated circuit assembly.

Furthermore, as shown in FIG. 4, the third semiconductor devices are positioned on the side of the third wafer layer that is closer to the fourth insulation layer. This means that face-to-face hybrid bonding is performed between the third bare die and the second bare die, while back-to-face hybrid bonding is carried out between the third bare die and the first bare die. This configuration significantly enhances the compatibility of 3D wafer stacking processes within the same third bare die.

Furthermore, the third semiconductor devices are electrically connected to the internal routing layer of the third insulation layer outside the reserved locations for the through vias, and/or electrically connected to the internal routing layer of the fourth insulation layer outside the reserved locations for the through vias. In other words, when the third semiconductor devices are electrically connected to the internal routing layer of either the third insulation layer or the fourth insulation layer, they are also electrically connected to the first and second semiconductor devices. This approach greatly reuses the available routing space, while enabling data transmission between the third semiconductor devices and the first and second semiconductor devices. As a result, when the third semiconductor devices are logic devices, the overall computational efficiency is improved; when they are memory devices, the overall memory efficiency is enhanced; or, in general, the efficiency of near-memory computing is significantly increased.

The following describes a method for processing the integrated circuit assembly in accordance with other embodiments of the present invention, with reference to FIG. 5. The processing method shown in FIG. 5 includes the following steps:

S510: forming a third initial insulation layer and a fourth initial insulation layer on both surfaces of a third wafer layer, respectively.

S520: forming a through via extending through the third wafer layer at a reserved location in an extending direction of the third wafer layer.

S530: forming a routing layer at a first routing point based on the through via in the third initial insulation layer, and forming a routing layer at the second routing point based on the through via in the fourth initial insulation layer.

S540: forming a third bonding point in the routing layer of the third initial insulation layer aligned with a first bonding point of a first bare die, and forming a fourth bonding point in the routing layer of the fourth initial insulation layer aligned with a second bonding point of a second bare die.

S550: forming an insulation layer on the routing layer of the third initial insulation layer to form a third insulation layer, and depositing an insulation layer on the routing layer of the fourth initial insulation layer to form a fourth insulation layer.

In the embodiment of the present invention, the routing layer is formed at the first routing point in the third initial insulation layer based on the through vias, which results in the formation of an internal routing layer in the third insulation layer. Similarly, the routing layer is formed at the second routing point in the fourth initial insulation layer based on the through vias, resulting in the formation of an internal routing layer in the fourth insulation layer. These routing layers enable electrical connections between the first routing point and the first bonding point, as well as between the second routing point and the second bonding point, thereby improving the flexibility of the electrical connection between the first bonding point and the second bonding point. Additionally, semiconductor devices can be formed in the third wafer layer, making the solution compatible with 3D wafer stacking technology and enhancing the processing efficiency of 3D wafer packaging.

In other examples, the processing method further includes forming a third semiconductor device outside the reserved locations in the extending direction of the third wafer layer. Accordingly, forming the third initial insulation layer and the fourth initial insulation layer on both surfaces of the third wafer layer includes: forming the fourth initial insulation layer on the side of the third wafer layer where the third semiconductor device is located, and forming the third initial insulation layer on the other side of the third wafer layer. This process reliably forms Through-Silicon Vias (TSVs), ensuring that the ends of the TSVs are positioned inside the third and fourth insulation layers, thereby enhancing the reliability of the routing functions of the routing die. Furthermore, internal routing layers are reliably formed within the third and fourth insulation layers, and these internal routing layers do not occupy the internal space of the third wafer layer, improving the compactness of devices within the third wafer layer.

Furthermore, the processing method also includes: depositing a first insulation layer on the side of the first wafer layer where the first semiconductor devices are formed to create the first bare die, and depositing a second insulation layer on the side of the second wafer layer where the second semiconductor devices are formed to create the second bare die. This process is compatible with the already-formed first and second bare dies. By taking into account the predetermined bonding point layout of the first and second bare dies, and through the design and fabrication of the third bare die, the reuse rate of the first and second bare dies is greatly improved. Additionally, this method is compatible with the device compactness brought by 3D wafer stacking technology, as well as the high data storage and computational efficiency between devices.

It should be noted that, depending on implementation needs, the various components/steps described in the embodiments of the present invention may be split into more components/steps, or two or more components/steps or parts of their operations may be combined into new components/steps to achieve the objectives of the embodiments of the present invention.

The methods described in the embodiments of the present invention can be implemented in hardware or firmware, or realized as software or computer code stored on recording media (such as CD-ROMs, RAM, floppy disks, hard disks, or magneto-optical disks), or as computer code originally stored on remote recording media or non-transitory machine-readable media and downloaded over a network to be stored on local recording media. Thus, the methods described herein can be stored as software processes on recording media using general-purpose computers, dedicated processors, or programmable or dedicated hardware (such as Application-Specific Integrated Circuits (ASIC) or Field-Programmable Gate Arrays (FPGA)). It is understood that a computer, processor, microcontroller, or programmable hardware includes storage components (e.g., Random Access Memory (RAM), Read-Only Memory (ROM), flash memory, etc.) that store or receive software or computer code. When the software or computer code is accessed and executed by the computer, processor, or hardware, it implements the methods described herein. Additionally, when a general-purpose computer accesses the code for implementing the methods shown here, the execution of the code transforms the general-purpose computer into a special-purpose computer for performing the methods demonstrated here.

A person of ordinary skill in the art will recognize that the units and method steps of the various examples described in connection with the embodiments disclosed herein can be implemented using electronic hardware, or a combination of computer software and electronic hardware. Whether these functions are performed in hardware or software depends on the specific application and design constraints of the technical solution. A skilled professional may implement the described functions using different methods for each specific application, but such implementations should not be considered beyond the scope of the embodiments of the present invention.

The above embodiments are provided solely to illustrate the embodiments of the present invention and are not intended to limit the scope of the invention. A person of ordinary skill in the relevant technical field may make various changes and modifications without departing from the spirit and scope of the embodiments of the present invention. Therefore, all equivalent technical solutions should also be considered within the scope of the embodiments of the present invention. The scope of patent protection for the embodiments of the present invention should be defined by the claims.

What is claimed is:

1. An integrated circuit assembly, comprising:
a first bare die, formed by a first wafer layer and a first insulation layer, wherein a first semiconductor device is formed in the first wafer layer, and the first semiconductor device forms a first bonding point on the first insulation layer;
a second bare die, formed by a second wafer layer and a second insulation layer, wherein a second semiconductor device is formed in the second wafer layer, and the second semiconductor device forms a second bonding point on the second insulation layer;
a third bare die, formed by a third wafer layer, a third insulation layer, and a fourth insulation layer, wherein a third bonding point is formed in the third insulation layer, and a fourth bonding point is formed in the fourth insulation layer, the third bonding point and the fourth bonding point are electrically connected through interior of the third wafer layer,
wherein the third bare die is disposed between the first bare die and the second bare die, the third insulation layer and the first insulation layer are hybrid bonded by aligning the third bonding point with the first bonding point, and the fourth insulation layer and the second insulation layer are hybrid bonded by aligning the fourth bonding point with the second bonding point.

2. The integrated circuit assembly according to claim 1, wherein a through via is formed in the third bare die, and the third bonding point is electrically connected to the fourth bonding point via the through via.

3. The integrated circuit assembly according to claim 2, wherein a first routing point is formed in the third insulation layer at the through via, and a second routing point is formed in the fourth insulation layer at the through via, wherein the first routing point is electrically connected to the third bonding point via an internal routing layer within the third insulation layer, the second routing point is electrically connected to the fourth bonding point via an internal routing layer within the fourth insulation layer, and the first routing point and the second routing point are electrically connected inside the through via.

4. The integrated circuit assembly according to claim 3, wherein a distance between the first routing point and the third bonding point in an extending direction of each wafer layer is less than the distance between the first bonding point and the second bonding point in the extending direction, and the distance between the second routing point and the fourth bonding point in the extending direction of each wafer layer is less than the distance between the first bonding point and the second bonding point in the extending direction.

5. The integrated circuit assembly according to claim 1, wherein a third semiconductor device is formed outside a reserved location of a through via in an extending direction of the third wafer layer.

6. The integrated circuit assembly according to claim 5, wherein the third semiconductor device is positioned on a side of the third wafer layer that is closer to the fourth insulation layer.

7. The integrated circuit assembly according to claim 5, wherein the third semiconductor device is electrically connected to an internal routing layer of the third insulation layer outside the reserved location of the through via, and/or the third semiconductor device is electrically connected to the internal routing layer of the fourth insulation layer outside the reserved location of the through via.

8. The integrated circuit assembly according to claim 1, wherein the first semiconductor device is a logic device, and the second semiconductor device is a memory device.

9. A system-on-chip, comprising:
an integrated circuit assembly according to claim 1.

10. A method for processing an integrated circuit assembly, comprising:
forming a third initial insulation layer and a fourth initial insulation layer on both surfaces of a third wafer layer, respectively;
forming a through via extending through the third wafer layer at a reserved location in an extending direction of the third wafer layer;
forming a routing layer at a first routing point in the third initial insulation layer based on the through via, and forming a routing layer at a second routing point in the fourth initial insulation layer based on the through via;
forming a third bonding point in the routing layer of the third initial insulation layer aligned with a first bonding point of a first bare die, and forming a fourth bonding point in the routing layer of the fourth initial insulation layer aligned with a second bonding point of a second bare die;
forming an insulation layer on the routing layer of the third initial insulation layer to form a third insulation layer, and depositing an insulation layer on the routing layer of the fourth initial insulation layer to form a fourth insulation layer.

11. The method according to claim 10, wherein the method further comprises:
forming a third semiconductor device outside the reserved location in the extending direction of the third wafer layer;
forming a third initial insulation layer and a fourth initial insulation layer on both surfaces of the third wafer layer, including:
forming the fourth initial insulation layer on a side of the third wafer layer wherein the third semiconductor device is formed, and forming the third initial insulation layer on the other side of the third wafer layer.

12. The method according to claim 10, wherein the method further comprises:
forming a first insulation layer on a side of a first wafer layer where a first semiconductor device is formed to create the first bare die;
forming a second insulation layer on the side of a second wafer layer where a second semiconductor device is formed to create the second bare die.
